(19) United States
(12) Patent Application Publication
(10) Pub. No.: US 2003/0219942 A1
(43) Pub. Date: Nov. 27, 2003

(54) Methods of forming capacitors and integrated circuit devices including tantalum nitride

(76) Inventors: Kyung-In Choi, Gyeonggi-do (KR); Gil-Heyun Choi, Gyeonggi-do (KR); Byung-Hee Kim, Seoul (KR); Sang-Bum Kang, Seoul (KR)

Correspondence Address: MYERS BIGEL SIBLEY & SAJOVEC, PO BOX 37428, RALEIGH, NC, 27627, US

(21) Appl. No.: 10/408,631

(22) Filed: Apr. 7, 2003

(30) Foreign Application Priority Data
May 25, 2002 (KR) 2002-29102

(51) Int. Cl. H01L 21/8234; H01L 21/8244; H01L 21/8242; H01L 21/20; H01L 21/44

(52) U.S. Cl. 438/253; 438/396; 438/681

(57) ABSTRACT

Methods of forming a capacitor can include forming a capacitor electrode including tantalum nitride. The capacitor electrode can be formed using a tantalum precursor including tantalum elements and bonding elements that are chemically bonded to the tantalum elements. Moreover, the tantalum precursor can include at least one of a tantalum amine derivative and/or a tantalum halide derivative. Related methods of forming integrated circuit devices are also discussed.

### RELATED APPLICATIONS

This application claims priority from Korean Patent Application No. 2002-29102, filed on May 25, 2002, the disclosure of which is herein incorporated by reference in its entirety.

### BACKGROUND OF THE INVENTION

1. Field of the Invention

The present invention relates to methods of forming capacitors, and more particularly, to methods of forming capacitor electrodes.

2. Description of the Related Art

Generally, a dynamic random access memory (DRAM) cell, one of the most widespread semiconductor devices, includes an access transistor and a storage capacitor. As memory cells have been developed to provide higher integration densities, capacitors may be desired to be as small as possible. That is, capacitors may be desired that provide a high storage capacitance while occupying as little space as possible. Accordingly, it may be desirable to increase storage capacitances of capacitors without enlarging a substrate surface occupied thereby.

A storage capacitance C of a capacitor can be represented using the following equation:

$$C = {ϵ}_{0} ϵ \frac{A}{d} ,$$

where, ε₀ is a dielectric constant of a vacuum, ε is a dielectric constant of the dielectric material of the capacitor, A is an effective area of the capacitor, and d is a thickness of the dielectric material.

According to the above exquation of the storage capacitance, the capacitance of a capacitor can be increased by: i) using a dielectric material with a higher dielectric constant; ii) increasing an effective area of the capacitor; and/or iii) reducing the thickness of the dielectric material. Recently, metal oxides with a high dielectric constant (such as Ta₂O₅, TiO₂, Al₂O₃, Y₂O₃, ZrO₂, HfO₂, BaTiO₃, and/or SrTiO₃) have been used as dielectric materials. A capacitor using a metal oxide as the dielectric material is disclosed in U.S. Pat. No. 5,316,982 (issued to Taniguchi), the disclosure of which is hereby incorporated herein in its entirety by reference.

When a metal oxide is used as a dielectric layer of a semiconductor device, however, the metal oxide may have a strong tendency to react with a lower electrode or an upper electrode of the capacitor because an oxygen (O) component of the metal oxide may react strongly with a silicon (Si) component of capactior electrodes including polysilicon. As a result, a silicon oxide layer may be formed on a boundary surface between the electrode layer and the dielectric layer of the capacitor on the semiconductor device, thereby changing an effective dielectric constant of the dielectric material. That is, use of metal oxide as a dielectric layer may result in formation of a silicon oxide layer that degrades capacitor performance and decreases reliability of the semiconductor device.

Accordingly, capacitor electrodes that may not readily react with a metal oxide capacitor dielectric and/or that may provide reliable capacitor performance may be desired.

### SUMMARY OF THE INVENTION

According to embodiments of the present invention, methods of forming a capacitor can include forming a capacitor electrode including tantalum nitride. More particularly, the capacitor electrode can be formed using a tantalum precursor including tantalum elements and bonding elements that are chemically bonded to the tantalum elements.

In addition, the tantalum precursor can include at least one of a tantalum amine derivative and/or a tantalum halide derivative. The tantalum amine derivative can include at least one of Ta(NR₁)(NR₂R₃)₃(where each of R₁, R₂, and R₃ are selected from an H and/or C₁-C₆ alkyl group), Ta(NR₁R₂)₅(where each of R₁ and R₂ are selected from an H and/or C₁-C₆ alkyl group), Ta(NR₁R₂)ₓ(NR₃R₄)₅₋ₓ (where each of R₁, R₂, R₃ and R₄ are selected from H and/or C₁-C₆ alkyl group and x is selected from 1, 2, 3 or 4), or terbutylimido-tris-diethylamido tantalum (TBTDET:(Net₂)₃Ta=NBu^{t}). The tantalum halide derivative can include at least one of TaF₅, TaCl₅, TaBr₅ and/or Tal₅. The tantalum precursor can also be introduced in a gaseous state. The capacitor electrode layer can be formed at a temperature in a range of about 100° C. to about 650° C. and at a pressure in a range of about 0.3 to about 30 Torr.

At least a portion of the bonding elements can include at least one ligand-bonded element that is ligand-bonded to a respective tantalum element. Moreover, forming the capacitor electrode can include introducing the tantalum precursor to a substrate, chemisorbing a portion of the tantalum precursor onto the substrate, removing from the substrate a portion of the tantalum precursor that has not been chemisorbed onto the substrate, and removing the ligand-bonded elements of the chemisorbed tantalum precursor from the chemisorbed tantalum precursor. In addition, introducing the tantalum precursor, chemisorbing a portion of the tantalum precursor, removing a portion of the tantalum precursor, and removing the ligand-bonded elements can be repeated at least once.

A residual material around the substrate can be removed when removing the ligand-boded elements. The ligand-bonded elements can be removed using a removing gas including at least one of H₂, N₂, NH₃, SiH₄, and/or Si₂H₆, and the removing gas can be activated as a plasma remote from the substrate. The non-chemisorbed tantalum precursor can be removed using an inert gas. After forming the capacitor electrode layer, the capacitor electrode layer can be treated using a post treatment gas comprising at least one of H₂, N₂, NH₃, SiH₄, and/or Si₂H₆, and the post treatment gas can be activated as a plasma.

Forming the capacitor electrode layer can also include introducing a tantalum amine derivative as the tantalum precursor to a substrate; introducing at least one of H₂ gas, N₂ gas, and/or a compound gas including nitrogen (N) atom(s), to the substrate; generating plasma ions of the at least one of the H₂ gas, the N₂ gas, and/or the compound gas including nitrogen (N) atom(s), and of the tantalum amine derivative; and forming a thin film including tantalum nitride on the substrate by reacting the plasma ions with the substrate.

After forming the thin film, the thin film can be post treated using a post treatment gas comprising at least one of H₂, NH₃, N₂, SiH₄, and/or Si₂H₆, and the post treatment gas can be activated as a plasma. In addition, the compound gas including nitrogen (N) atom(s) can include at least one of NH₃ gas or N₂H₂ gas. The H₂ gas, the N₂ gas, and/or the compound gas including nitrogen (N) atom(s) can also be activated as a plasma.

Forming the capacitor electrode can also be preceded by providing an integrated circuit substrate including a source/drain region therein, wherein the capacitor electrode is formed on the integrated circuit substrate and wherein the capacitor electrode is electrically coupled with the source/drain region. Alternately, forming the capacitor electrode is preceded by providing an integrated circuit substrate, forming an initial capacitor electrode on the integrated circuit substrate, and forming a capacitor dielectric layer on the initial capacitor electrode opposite the integrated circuit substrate, wherein the capacitor electrode layer is formed on the capacitor dielectric layer opposite the initial capacitor electrode.

Methods can also include forming a dielectric layer on the capacitor electrode layer; and forming an opposing capacitor electrode on the dielectric layer opposite the capacitor dielectric layer. In addition, the dielectric layer can include a metal oxide comprising at least one of Ta₂O₅, TiO₂, Al₂O₃, Y₂O₃, ZrO₂, HfO₂, BaTiO₃, and/or SrTiO₃. In addition, the opposing capacitor electrode can include a tantalum nitride layer. Alternately, the opposing capacitor electrode can include at least one of polysilicon, ruthenium (Ru), platinum (Pt), iridium (Ir), titanium nitride (TaN), tantalum nitride (TaN), and/or tungsten nitride (WN). In addition, a capping layer such as a tantalum nitride capping layer can be formed on the opposing capacitor electrode opposite the dielectric layer.

According to additional embodiments of the present invention, methods of forming an integrated circuit device can include forming a conductive layer including tantalum nitride on an integrated circuit substrate using a tantalum precursor including tantalum elements and bonding elements that are chemically bonded to the tantalum elements. The tantalum precursor can include at least one of a tantalum amine derivative and/or a tantalum halide derivative.

The tantalum amine derivative can include at least one of Ta(NR₁)(NR₂R₃)₃ (where each of R₁, R₂, and R₃ are selected from an H and/or C₁-C₆ alkyl group), Ta(NR₁R₂)₅(where each of R₁ and R₂ are selected from an H and/or C₁-C₆ alkyl group), Ta(NR₁ R₂)ₓ(NR₃R₄)₅₋ₓ(where each of R₁, R₂, R₃ and R₄ are selected from H and/or C₁-C₆ alkyl group and x is selected from 1, 2, 3 or 4), or terbutylimido-tris-diethylamido tantalum (TBTDET:(Net₂)₃Ta=NBu^{t}). The tantalum halide derivative can inlcude at least one of TaF₅, TaCl₅, TaBr₅ and/or Tal₅. The tantalum precursor can be introduced in a gaseous state, and the conductive layer can be formed at a temperature in a range of about 100° C. to about 650° C. and at a pressure in a range of about 0.3 to about 30 Torr. In addition, at least a portion of the bonding elements can include at least one ligand-bonded element that is ligand-bonded to a respective tantalum element.

Forming the conductive layer can include introducing the tantalum precursor to the integrated circuit substrate, chemisorbing a portion of the tantalum precursor onto the integrated circuit substrate, removing from the integrated circuit substrate a portion of the tantalum precursor that has not been chemisorbed onto the integrated circuit substrate, and removing the ligand-bonded elements of the chemisorbed tantalum precursor from the chemisorbed tantalum precursor. In addition, introducing the tantalum precursor, chemisorbing a portion of the tantalum precursor, removing a portion of the tantalum precursor, and removing the ligand-bonded elements can be repeated at least once.

A residual material can also be removed from around the integrated circuit substrate when removing the ligand-boded elements, and the non-chemisorbed tantalum precursor can be removed using an inert gas. In addition, the ligand-bonded elements can removed using a removing gas including at least one of H₂, N₂, NH₃, SiH₄, and/or Si₂H₆, and the removing gas can be activated as a plasma remote from the substrate. After forming the conductive layer, the conductive layer can be treated using a post treatment gas comprising at least one of H₂, N₂, NH₃, SiH₄, and/or Si₂H₆, and the post treatment gas can be activated as a plasma.

Forming the conductive layer can further include introducing a tantalum amine derivative as the tantalum precursor to the integrated circuit substrate; introducing at least one of H₂ gas, N₂ gas, and/or a compound gas including nitrogen (N) atom(s), to the integrated circuit substrate; generating plasma ions of the at least one of the H₂ gas, the N₂ gas, and/or the compound gas including nitrogen (N) atom(s), and of the tantalum amine derivative; and forming a thin film including tantalum nitride on the integrated circuit substrate by reacting the plasma ions with the integrated circuit substrate. After forming the thin film, the thin film can be post treated using a post treatment gas comprising at least one of H₂, NH₃, N₂, SiH₄, and/or Si₂H₆, and the post treatment gas can be activated as a plasma. The compound gas including nitrogen (N) atom(s) can include at least one of NH₃ gas or N₂H₂ gas. The H₂ gas, the N₂ gas, and/or the compound gas including nitrogen (N) atom(s) can be activated as a plasma.

The integrated circuit substrate can include a source/drain region therein, and the capacitor electrode can be electrically coupled with the source/drain region. Alternately, forming the conductive layer can be preceded by forming an initial capacitor electrode on the integrated circuit substrate, and forming a capacitor dielectric layer on the initial capacitor electrode opposite the integrated circuit substrate, wherein the conductive layer is formed on the capacitor dielectric layer opposite the initial capacitor electrode.

Methods can also include forming a dielectric layer on the conductive layer, and forming an opposing capacitor electrode on the dielectric layer opposite the conductive layer. The dielectric layer can include a metal oxide such as Ta₂O₅, TiO₂, Al₂O₃, Y₂O₃, ZrO₂, HfO₂, BaTiO₃, and/or SrTiO₃, and the opposing capacitor electrode can include a tantalum nitride layer. The opposing capacitor electrode can include at least one of polysilicon, ruthenium (Ru), platinum (Pt), iridium (Ir), titanium nitride (TaN), tantalum nitride (TaN), and/or tungsten nitride (WN). In addition, a capping layer can be formed on the opposing capacitor electrode opposite the dielectric layer, and, the capping layer can include tantalum nitride (TaN).

### BRIEF DESCRIPTION OF THE DRAWINGS

FIGS. 1A to 1D are cross-sectional views illustrating methods of forming capacitor electrodes using atomic layer deposition (ALD) according to embodiments of the present invention.

FIG. 2 is a diagram illustrating a chemical vapor deposition (CVD) apparatus for forming capacitor electrodes according to embodiments of the present invention.

FIGS. 3A to 3G are cross-sectional views illustrating methods of forming capacitors according to embodiments of the present invention.

FIGS. 4 and 5 are graphs illustrating leakage current characteristics of capacitors formed using methods illustrated in FIGS. 3A to 3G.

### DESCRIPTION OF EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

According to first embodiments of the present invention, a first electrode layer including tantalum nitride can be deposited on a semiconductor substrate using a tantalum precursor. The tantalum precursor can include tantalum elements and bonding elements that are chemically bonded to the tantalum elements. A portion and/or all of the bonding elements can include at least one ligand-bonded element, which is ligand-bonded to the tantalum element.

The tantalum precursor can include a tantalum amine derivative or a tantalum halide precursor. More particularly, the tantalum amine derivative can include Ta(NR₁)(NR₂R₃)₃(where R₁, R₂, and R₃ are selected from an H and/or C₁-C₆ alkyl group and can be the same or different from each other), Ta(NR₁R₂)₅, (where R₁ and R₂ are selected from an H and/or C₁-C₆ alkyl group and can be the same or different from each other), Ta(NR₁ R₂)ₓ (NR₃R₄)₅₋ₓ (where R₁, R₂, R₃ and R₄ are selected from an H and/or C₁-C₆ alkyl group and can be the same or different from each other and x is selected from 1, 2, 3 or 4), and/or terbutylimido-tris-diethylamido tantalum (TBTDET:(Net₂)₃Ta=NBu^{t}). Examples of a tantalum halide derivative include TaF₅, TaCl₅, TaBr₅ and/or Tal₅.

When the first electrode layer is formed at a temperature above about 650° C. using a tantalum precursor, the first electrode layer may not be properly deposited on the substrate because the tantalum precursor may be completely decomposed and particles may be generated. On the other hand, when the first electrode layer is formed at a temperature less than about 100° C., the first electrode layer may not be properly deposited on the substrate because the tantalum precursor may not be decomposed. According to some embodiments, the first electrode layer may be deposited in a temperature in the range of about 100° C. to 650° C. According to additional embodiments, the first electrode layer can be deposited at a pressure in a range of between about 0.3 Torr and about 30 Torr when the temperature is in the range of about 100° C. to 650° C. In addition embodiments, the tantalum precursor can be introduced in a gaseous state using a bubbler or a liquid delivery system (LDS). The tantalum precursor can be deposited on the substrate using ALD (Atomic Layer Deposition) and/or CVD (Chemical Vapor Deposition).

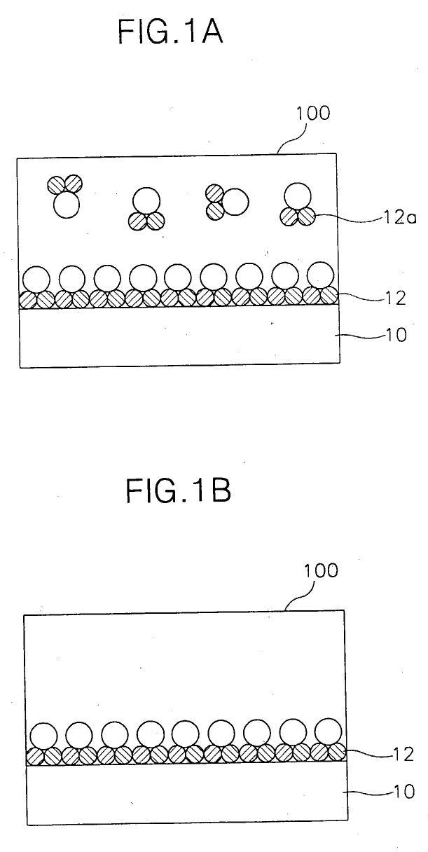

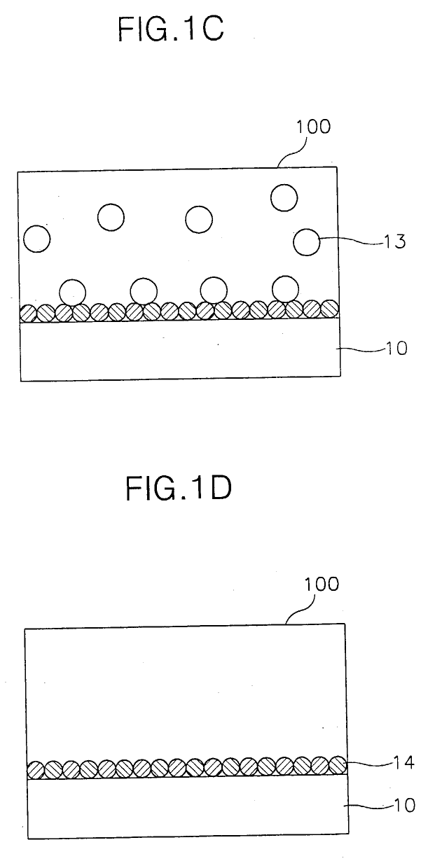

Methods of forming a first electrode layer using ALD will be described with reference to the accompanying drawings. FIGS. 1A to 1D are cross-sectional views illustrating methods of forming a capacitor electrode using atomic layer deposition (ALD) according to embodiments of the present invention.

A substrate on which the first electrode layer of the capacitor will be formed is placed in a processing chamber 100. The processing chamber 100 is then maintained at a pressure in a range of about 0.3 Torr to about 30 Torr, and the substrate is heated to a temperature of less than about 650° C.

Referring to FIG. 1A, the tantalum precursor 12a is introduced into the processing chamber 100, and then some of the tantalum precursor 12a is chemisorbed (chemically absorbed) onto the substrate. As shown in FIG. 1B, an inert gas is introduced into the processing chamber 100. As a result, non-chemisorbed tantalum precursors 12a are removed from the substrate and from the processing chamber. In some embodiments, a nitrogen (N₂) gas or an argon (Ar) gas can be used as the inert gas. Referring to FIG. 1C, a removing gas (not shown) is introduced into the processing chamber 100, and the ligand-bonded elements 13 of the chemisorbed tantalum precursors 12 are removed from the tantalum precursors 12a. The ligand-bonded elements can be removed using H₂, N₂, NH₃, SiH₄, and/or Si₂H₆, for example, alone or in combination. These compounds can be activated through a remote plasma process that avoids damage to the substrate.

Finally, a purge gas (not shown) is introduced into the processing chamber 100, and any removing gas remaining in the processing chamber 100 is displaced. As a result, an atomic layer 14 including tantalum nitride can be deposited on the substrate as shown in FIG. 1D. The first electrode layer including tantalum nitride can be deposited relatively easily on the substrate by repeating the deposition of the atomic layer 14. In addition, removing the non-chemisorbed tantalum precursor from the substrate using the inert gas and removing the ligand-bonded elements from the tantalum precursor using the removing gas can be repeated many times so as to reduce inclusion of impurities in the tantalum nitride electrode layer. In other words, steps of forming the atomic layer 14 including tantalum nitride can be repeated to provide a desired thickness of the first electrode layer.

In addition, a post treatment process for the first electrode layer can be carried out using H₂, N₂, NH₃, SiH₄, Si₂H₆, or a combination thereof, which can be activated through a remote plasma process or a direct plasma process. After forming the first electrode layer, the post treatment process can be used to more completely remove any impurities remaining in the first electrode layer. While a remote plasma process can generate a radio frequency plasma gas outside of the processing chamber 100 and provide the plasma gas into the processing chamber 100, a direct plasma process can generate the radio frequency plasma gas inside of the processing chamber 100.

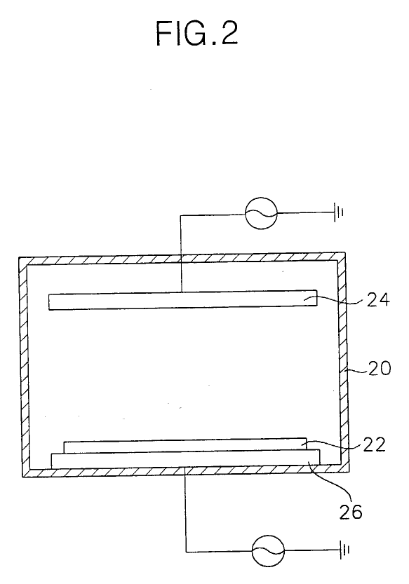

A method of forming the first electrode layer by using a direct plasma type CVD process will be described with reference to FIG. 2. FIG. 2 is a diagram illustrating a chemical vapor deposition (CVD) apparatus for forming a capacitor electrode according to embodiments of the present invention.

A substrate 22 on which the first electrode layer will be formed is placed in a processing chamber 20. The processing chamber 20 is set at a pressure in a range of about 0.3 Torr to about 30 Torr, and the substrate 22 is heated to a temperature less than about 650° C. Subsequently, tantalum amine derivatives (not shown) are introduced into the processing chamber 20, and then gaseous reactants are also provided into the processing chamber 20. According to additional embodiments, a hydrogen (H₂) gas, a nitrogen (N2) gas or a compound gas including nitrogen (N) atom(s) can be used as the gaseous reactants, alone or in combination. These gaseous reactants can be used as activated. According to still additional embodiments, an NH₃ gas or an N₂H₂ gas can be used as the compound gas including nitrogen (N) atom(s).

Power is applied to electrodes 24 and 26 of the processing chamber 20 so that the tantalum amine derivatives are activated through the remote plasma process or the direct plasma process, and changed into plasma ions. Subsequently, the plasma ions react with each other onto the substrate 20 to thereby deposit the first electrode layer including tantalum nitride. As one embodiment of the present invention, the direct plasma process can be used in the CVD apparatus as shown in FIG. 2.

A post treatment process for the first electrode layer can also be carried out using H₂, N₂, NH₃, SiH₄, Si₂H₆, and/or a combination thereof, which can be activated through the remote plasma process or the direct plasma process, after forming the first electrode layer to more completely remove any impurities remaining in the first electrode layer. Accordingly, a first electrode layer including tantalum nitride can be formed through ALD or CVD using the tantalum precursor.

A dielectric layer including a metal oxide is deposited on the first electrode layer. Examples of metal oxides for the dielectric layer may include Ta₂O₅, TiO₂, Al₂O₃, Y₂O₃, ZrO₂, HfO₂, BaTiO₃, SrTiO₃, etc. These layers may be formed alone or a composite layer thereof that includes at least two of these layers may be used.

A second electrode layer is deposited on the dielectric layer. Examples of the second electrode layer includes a polysilicon thin film, a ruthenium (Ru) thin film, a platinum (Pt) thin film, an iridium (Ir) thin film, a titanium nitride (TaN) thin film, a tantalum nitride (TaN) thin film, tungsten nitride (WN) thin film, etc. Furthermore, when the second electrode layer is not a tantalum nitride (TaN) thin film, a capping layer may be further deposited on the second electrode layer. The capping layer can include a tantalum nitride thin film. The second electrode layer can be deposited in the same manner as in the first electrode layer in case the second electrode layer includes tantalum nitride.

As a result, a capacitor can be manufactured to have a first electrode layer corresponding to a lower electrode, the dielectric layer, and a second electrode layer corresponding to an upper electrode on a semiconductor substrate. According to embodiments of the present invention, the first electrode layer may provide a storage electrode, and the second electrode layer may provide a plate electrode of a capacitor used in an integrated circuit device.

According to additional embodiments of the present invention, the first electrode layer and/or the second electrode layer can be formed to include tantalum nitride so that the metal oxide having a high dielectric constant can be used as the dielectric layer of the semiconductor capacitor. As a result, a storage capacitance of a capacitor can be increased.

A chemical reaction mechanism for forming electrode layers (the first and/or the second electrode layer) including tantalum nitride is described as follows according to embodiments of the present invention. Hereinafter, the chemical reaction for removing the tantalum precursor using an inert gas is referred to as a purification reaction, and the chemical reaction for removing the ligand-bonded element using the removing gas is referred to as a removing reaction. During the removing reaction, the removing gas reacts with the ligand-bonded element, and the ligand-bonded element is removed from the tantalum precursor, because the reactivity of the removing gas to the ligand-bonded element is higher than that of the ligand-bonded element to the tantalum precursor.

Terbutylimido-tris-diethylamido-tantalum ((NEt₂)₃Ta=Nbu^{t}, hereinafter simply referred to as “TBTDET”) can also be used as the tantalum precursor. A part of the TBTDET is chemisorbed onto the substrate, and the non-chemisorbed TBTDET is removed from the substrate during the purification reaction. The ligand-bonded elements are then removed through the removal reaction using the reactivity difference between the ligand-bonded elements and the removal gas to the tantalum precursor. During the removal reaction, the TBTDET is not influenced by the removing gas, since the TBTDET includes a double bond of Ta=N. Accordingly, the ligand-bonded elements are only removed during the removal reaction, so that an atomic layer comprising Ta=N can be deposited on the substrate.

A variety of deposition methods of depositing the tantalum nitride, (different from chemical reaction mechanisms according to embodiments of the present invention), are disclosed in U.S. Pat. No. 6,268,288 issued to Hautala et al., U.S. Pat. No. 6,203,613 issued to Gates et al.; Korean Patent Laid-Open Publication No. 2001-45960; Korean Patent Laid-Open Publication No. 1997-18573; and in an article by Kang et al., entitled “Plasma-Enhanced Atomic Layer Deposition of Tantalum Nitrides Using Hydrogen Radicals as a Reducing Agent”, Electrochemical and Solid-State Letters, 4(4) C17-19 (2001). The disclosures of each of these patents, publications, and articles are hereby incorporated herein in their entirety by reference.

According to embodiments of the present invention, removing the ligand-bonded element using the removing gas may be different than a substitution reaction using hydrogen radicals as a reducing agent. According to additional embodiments of the present invention, a power source may not need to be applied into the processing chamber when the tantalum nitride is deposited. Furthermore, deposition of a metal layer using CVD according to embodiments of the present invention can use tantalum amine derivatives as tantalum precursors, which may also be different from conventional deposition techniques using tantalum halide as tantalum precursors.

Hereinafter, examples of forming capacitors according to embodiments of the present invention are described with reference to the accompanying drawings.

### EXAMPLE I

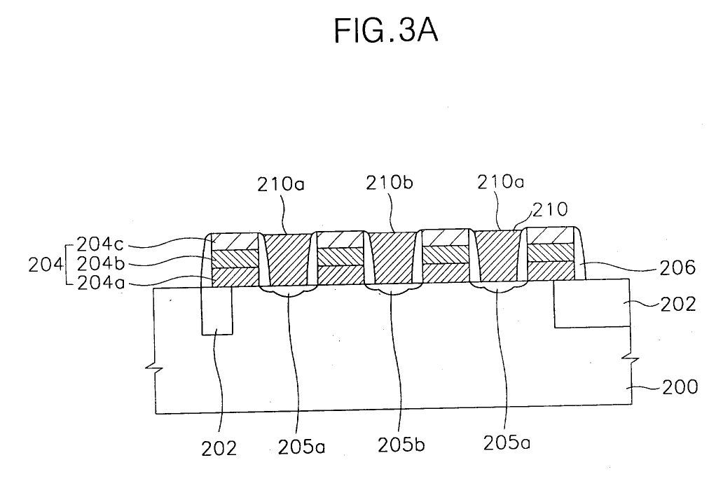

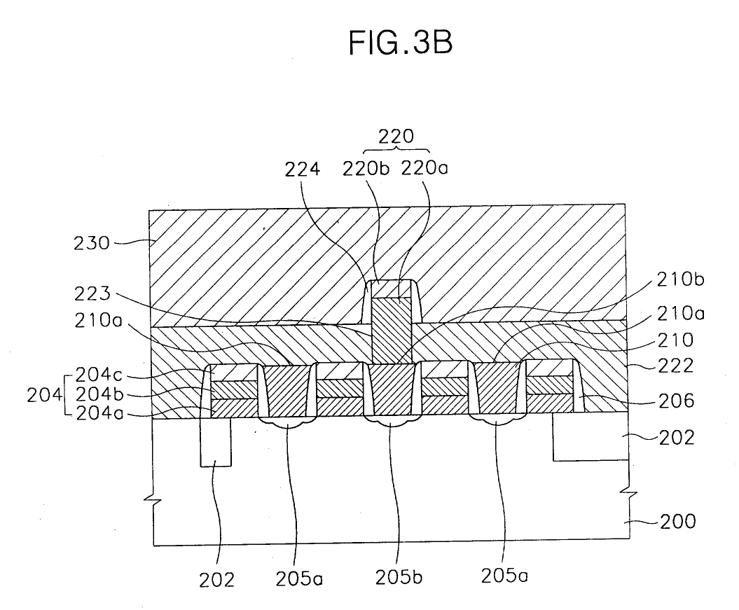

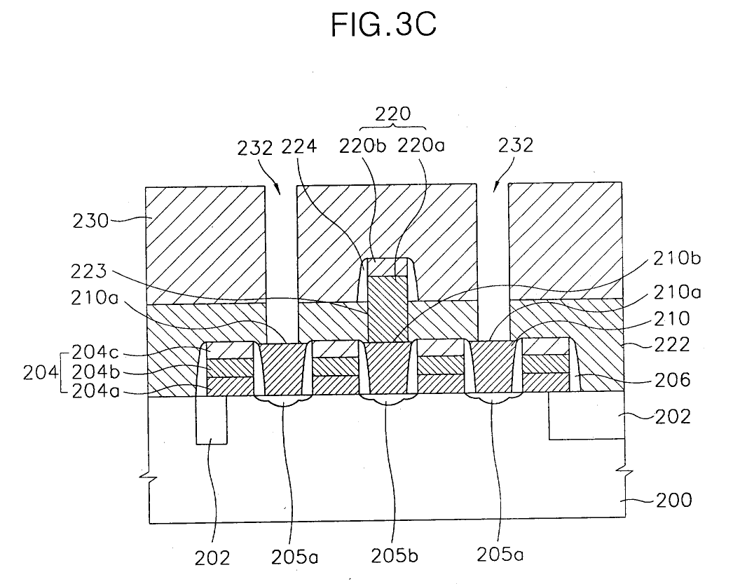

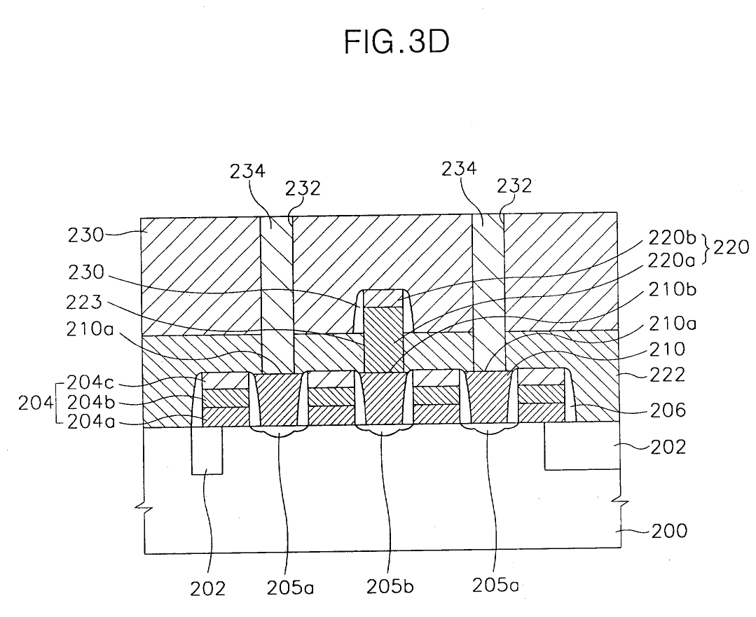

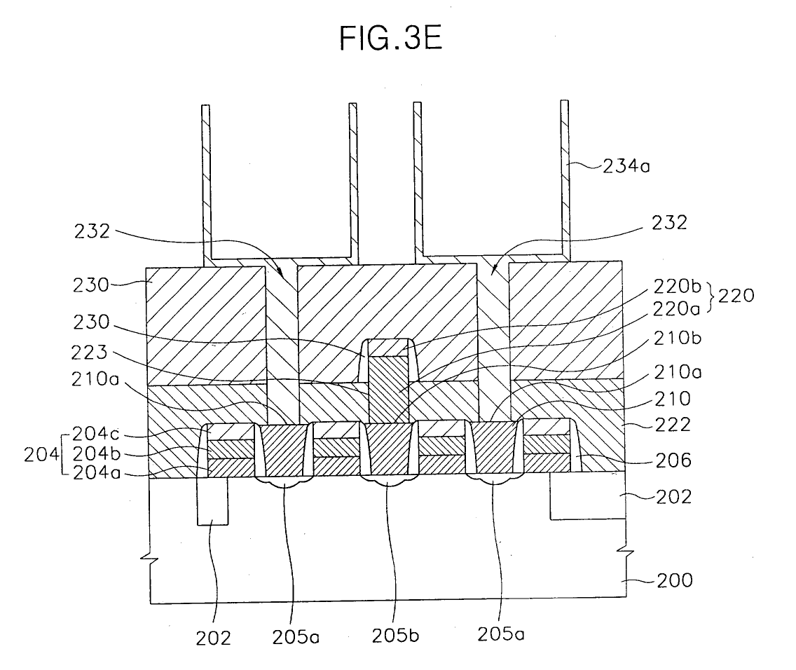

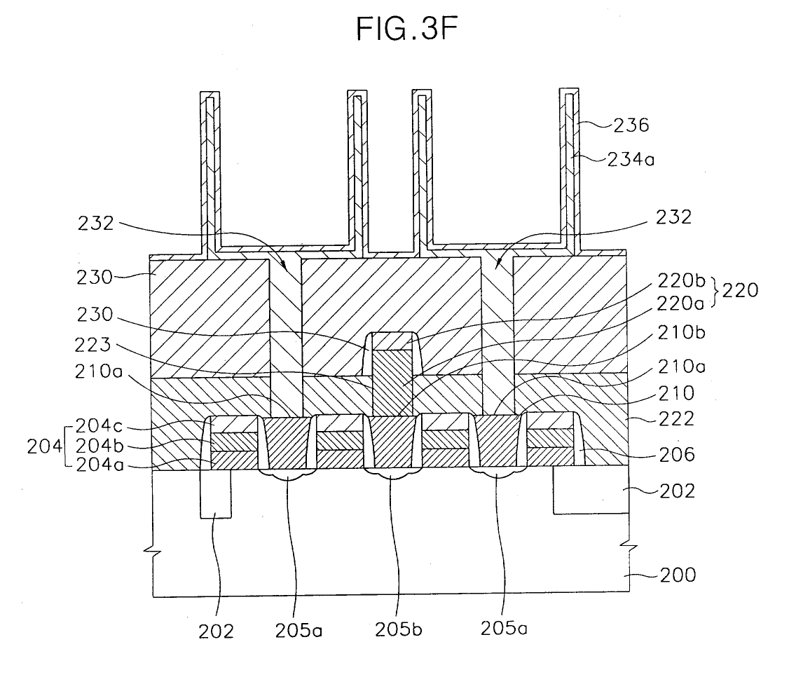

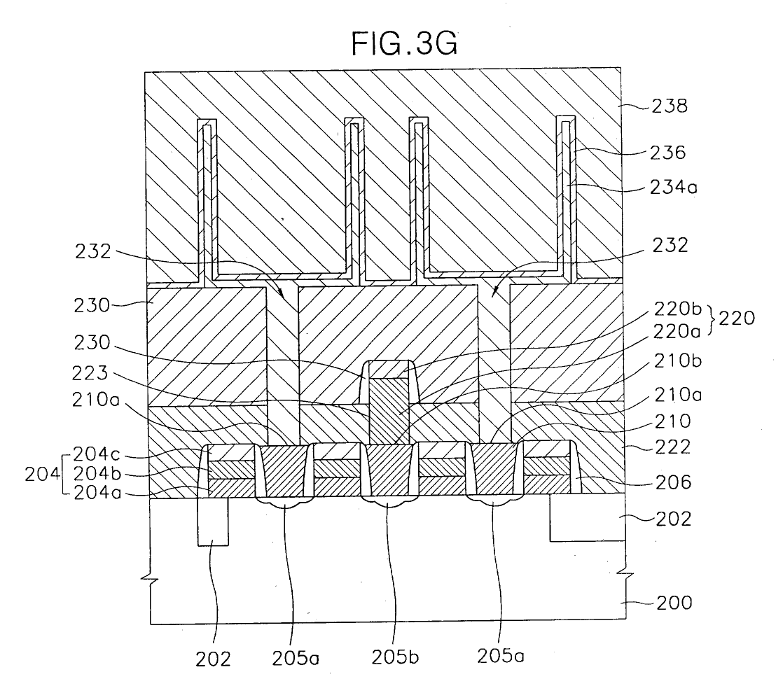

FIGS. 3A to 3G are cross-sectional views illustrating methods of forming a capacitor according to embodiments of the present invention.

Referring to FIG. 3A, a trench structure 202 can be formed on a semiconductor substrate 200 using conventional field isolation techniques so that the substrate 200 is separated into active and a non-active areas. Impurities can then be partially implanted into the substrate 200 to provide P-wells and N-wells. Subsequently, a polysilicon layer 204a, a tungsten silicide layer 204b and a silicon nitride layer 204c can be sequentially formed on the active area of the substrate 200 to form a gate pattern 204 corresponding to a word line of a DRAM cell. That is, the gate pattern 204 can have a polyside structure including a polysilicon layer 204a doped with a relatively high concentration of impurities and a tungsten silicide layer 204b formed on the polysilicon layer 204a. In addition, spacers 206 comprising silicon nitride can be formed on side surfaces of the gate pattern 204.

A source electrode 205a and a drain electrode 205b can be formed on a surface of the substrate 200 surrounding to the gate pattern 204 by implanting impurities using the gate pattern 204 as a mask. Accordingly, a transistor including the gate pattern 204, the source electrode 205a, and the drain electrode 205b is formed on the substrate 200. One of the source electrode 205a and the drain electrode 205b is connected to the lower electrode of the capacitor to provide a capacitor contact area, and the other is connected to a bit line structure of semiconductor device to provide a bit line contact area. According to some embodiments of the present invention, the source electrodes 205a provide respective contact areas, and the drain electrode 205b provides a bit line contact area.

Polysilicon can then be filled into spaces between the gate patterns 204 to provide capacitor contact pads 210a that make electrical contact with respective lower capacitor electrodes of respective capacitors and a bit line contact pad 210b that makes electrical contact with a bit line structure. The polysilicon 210 filling the capacitor contact areas corresponds to the capacitor contact pads 210a, and the polysilicon 210 filling the bit line contact area corresponds to the bit line contact pad 210b.

As shown in FIG. 3B, the bit line structure 220 is electrically connected to the bit line contact pad 210b. In particular, a first insulating interlayer 222 is deposited on the gate pattern 204 and the polysilicon 210 filled between the gate patterns 204. Then, the first insulating interlayer 222 is selectively etched using a photolithography process so that the bit line contact pad 210b is partially exposed to provide a bit line contact hole 223. Subsequently, tungsten 220a is deposited in the bit line contact hole 223 and on the first insulating interlayer 222. As a result, the tungsten 220a can completely fill the bit line contact hole 223. Then, silicon nitride 220b is deposited on the tungsten layer 220a. After depositing the silicon nitride 220b, the silicon nitride 220b layer and the tungsten layer 220a are selectively etched using a photolithography process to thereby form the bit line structure 220 including the tungsten 220a and the silicon nitride 220b.

Then, silicon nitride is deposited on the bit line structure 220 and the first insulating interlayer 222, and the silicon nitride layer is selectively etched to provide silicon nitride spacers 224 on side surfaces of the bit line structures 220. Accordingly, the tungsten 220a in the bit line structure 220 is covered with the silicon nitride 220b of the mask layer and surrounded with the silicon nitride of the spacers 224.

A second insulating interlayer 230 can be deposited on the bit line structure 220, the spacers 224, and the first insulating interlayer 222. The second insulating interlayer 230 can include silicon nitride, and can be deposited using high-density plasma deposition process.

Referring to FIG. 3C, the second insulating interlayer 230 and the first insulating interlayer 222 can be selectively etched to partially expose capacitor contact pads to thereby provide self-aligned contact holes 232. The etching rate on the silicon nitride of the bit line structure 220 and the spacer 224 may be different than the etching rate of the silicon nitride of the first and second insulating interlayers 222 and 230, which may cause the etch to proceed more quickly on the second insulating interlayer 230 and the first insulating interlayer 222 than on the silicon nitride of the bit line structure 220 and the spacer 224.

Referring to FIG. 3D, a lower electrode layer 234 of the capacitor can be formed by filling the self-aligned contact hole 232 using ALD or CVD according to some embodiments of the present invention, so that the lower electrode layer 234 can include tantalum nitride. A cylinder-shaped lower electrode 234a of the capacitor can be formed using a photolithography process on the lower electrode layer 234 as follows.

A first lower electrode material can be filled in the self-aligned contact hole 232, and then the first lower electrode material on the second insulating interlayer 230 can be polished through a chemical mechanical polishing (CMP) process. Accordingly, the first lower electrode material only fills the self-aligned contact hole 232 but does not extend onto the surface of the second insulating interlayer. Continuously, an oxide layer (not shown) can be successively deposited on the first lower electrode material that fills the self-aligned contact hole 232. The oxide layer can be patterned into a cylinder shape, and then a second lower electrode material can be deposited on the cylinder-shaped oxide layer. The oxide layer can be etched, and then the cylinder-shaped lower electrode layer 234a can be formed, as shown in FIG. 3E.

Referring to FIG. 3F, a dielectric layer 236 is formed on surfaces of the cylinder-shaped lower electrode layer 234a. According to some embodiments of the present invention, metal oxide can be used as the dielectric layer 236. Examples of materials for the dielectric layer 236 can include TA₂O₅, TiO₂, Al₂O₃, Y₂O₃, ZrO₂, HfO₂, BaTiO₃, and/or SrTiO₃. Combinations of the above referenced materials and/or layers thereof can also be used.

Referring to FIG. 3G, an upper electrode layer 238 of the capacitor is formed on the dielectric layer 236. The upper electrode layer 238 can include a thin film of tantalum nitride, polysilicon, ruthenium (Ru), platinum (Pt), iridium (Ir), titanium nitride (TaN), tantalum nitride (TaN), and/or tungsten nitride (WN). When including a thin film of tantalum nitride, the upper electrode layer 238 can be formed in the same manner as in the first electrode layer. Accordingly, the capacitor can include the lower electrode layer, the dielectric layer, and the upper electrode layer.

As described in the first example, the lower electrode layer and/or the upper electrode layer of the capacitor can be formed to include tantalum nitride, so that a capacitor according to embodiments of the present invention can use a metal oxide having a high dielectric constant as the dielectric layer.

### EXAMPLE 2

A self-aligned contact hole can be formed on a substrate in the same manner as in the first example. A lower electrode layer of the capacitor can be formed on the second electrode layer by filling the self-aligned contact hole with a lower electrode material. According to additional embodiments of the present invention, the lower electrode layer may include a thin film of tantalum nitride, polysilicon, ruthenium (Ru), platinum (Pt), iridium (Ir), titanium nitride (TaN), tantalum nitride (TaN), and/or tungsten nitride (WN). When including a thin film of tantalum nitride, the lower electrode layer can be formed in the same manner as discussed in the first example.

Then, the lower electrode layer can be etched using a conventional photolithography process to thereby form a cylinder-shaped lower electrode layer. A dielectric layer is formed on a surface of the cylinder-shaped lower electrode layer. According to still additional embodiments of the dielectric layer, a metal oxide can be deposited on a surface of the cylinder-shaped lower electrode layer. Examples of materials for the dielectric layer can include TA₂O₅, TiO₂, Al₂O₃, Y₂O₃, ZrO₂, HfO₂, BaTiO₃, and/or SrTiO₃.

Continuously, an upper electrode layer of the capacitor can be deposited on the dielectric layer using ALD or CVD according to some embodiments of the present invention, so that the upper electrode layer includes tantalum nitride. Accordingly, integrated circuit capacitors according to embodiments of the present invention can be formed to include the lower electrode layer, the dielectric layer, and the upper electrode layer.

As described in the second example, the lower electrode layer and/or the upper electrode layer of the capacitor can be formed to include tantalum nitride, so that capacitors according to second embodiments of the present invention can use a metal oxide having a high dielectric constant as the dielectric layer.

Hereinafter, characteristics of capacitors according to embodiments of the present invention are described.

Leakage Current Characteristic

To provide an investigation into leakage current characteristics of capacitors according to embodiments of the present invention, three types of capacitor specimens were prepared.

Specimen I includes a lower electrode layer of 200 Å thickness, a dielectric layer having a TaO layer of 90 Å thickness and an O₃ layer of 60 Å thickness, and an upper electrode layer of 100 Å thickness having tantalum nitride according to embodiments of the present invention. Specimen II includes a lower electrode layer of 200 Å thickness, a dielectric layer having a Ta₂O₅ layer of 90 Å thickness and an O₃ layer of 60 Å thickness, and an upper electrode layer of 800 Å thickness having tantalum nitride according to embodiments of the present invention. Specimen III includes a lower electrode layer of 200 Å thickness, a dielectric layer having a Ta₂O₅ layer of 90 Å thickness and an O₃ layer of 60 Å thickness, and an upper electrode layer of 800 Å thickness having titanium nitride.

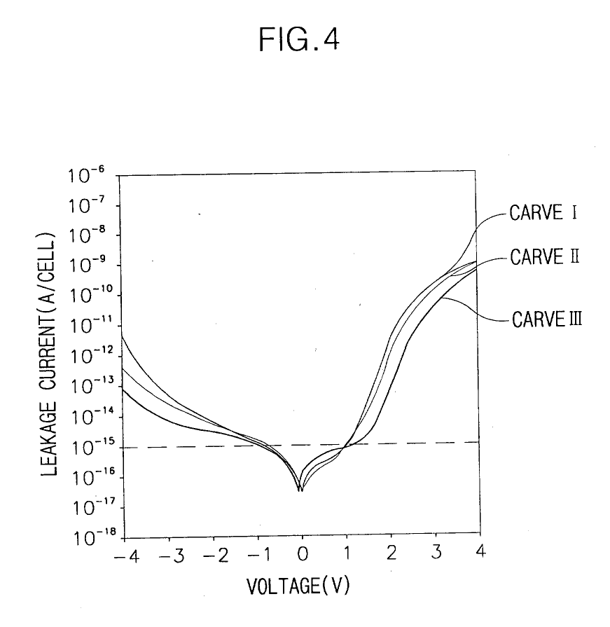

A voltage in a range of −4V to 4V was applied to both electrodes of the respective specimen capacitors. FIG. 4 is a graph showing a leakage current characteristic of the capacitor of Specimen I. In FIG. 4, curves I, II, and III show leakage current characteristics when the voltage is applied at temperatures of about 25° C., 85° C., and 125° C., respectively. Referring to FIG. 4, the leakage current characteristics may be acceptable irrespective of the temperature. Particularly, the graph of FIG. 4 shows that the leakage current is in a range of about 10⁻¹⁷A/cell to 10⁻¹⁵A/cell when the voltage was applied in a range of about −1V to +1V.

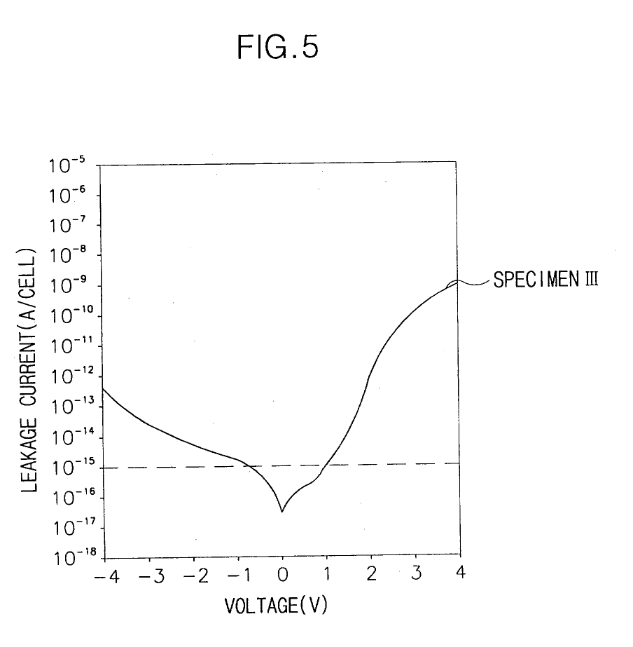

FIG. 5 is a graph showing a leakage current characteristic of the capacitor of specimen III. The graph as shown in FIG. 5 shows that the leakage current of the capacitor of specimen III is allowable.

Even though not shown in the attached drawings, investigation of the capacitor of specimen II showed that the leakage current was also in a range of about 10⁻¹⁷A/cell to 10⁻¹⁵A/cell when the voltage was applied in a range of about −1V to 1V. That is, it was noted that the integrated circuit capacitors including the first electrode layer and/or the second electrode layer according to embodiments of the present invention have good leakage current characteristics.

Storage Capacitance Characteristic

An investigation of the storage capacitance showed that an electric thickness oxide (ETO) of the specimen II is 25 Å, and the ETO of the specimen III is 27 Å, which indicates that the capacitor including the first electrode layer and/or the second electrode layer according to embodiments of the present invention have a good storage capacitance.

According to embodiments of the present invention, a metal oxide having a high dielectric constant can be used as a capacitor dielectric layer without significant chemical reaction between the dielectric layer and the electrode layers, thereby increasing a storage capacitance of a capacitor and providing steady capacitor performance even though the metal oxide is used as the dielectric layer.

Methods according to embodiments of the present invention may include forming a capacitor including a tantalum nitride layer as a lower electrode layer. Methods according to additional embodiments of the present invention may include forming a capacitor including a tantalum nitride layer as an upper electrode layer.

According to embodiments of the present invention, methods of forming a capacitor on a semiconductor device can include forming a first electrode layer including tantalum nitride on a semiconductor substrate using a tantalum precursor. Moreover, the tantalum precursor can include tantalum elements and bonding elements that are chemically bonded to the tantalum elements, and at least a portion of the bonding elements can include at least one ligand bonded element which is ligand-bonded to the tantalum element. A dielectric layer can be formed on the first electrode layer, and a second electrode layer can be formed on the dielectric layer.

According to additional embodiments of the present invention, methods of forming a capacitor on a semiconductor device can include forming a first electrode layer on a substrate and then forming a dielectric layer on the first electrode layer. A second electrode layer including tantalum nitride can be formed on the dielectric layer using a tantalum precursor. The tantalum precursor can include tantalum elements and bonding elements that are chemically bonded to the tantalum elements, and at least a portion of the bonding elements can include at least one ligand-bonded element which is ligand-bonded to the tantalum element.

Electrode layers of a capacitor on a semiconductor device can thus include tantalum nitride, and therefore, chemical reaction between electrode layers and the dielectric layer can be reduced even when the dielectric layer comprises a metal oxide. In addition, a dielectric constant of the dielectric layer can be increased due to one or both electrodes including tantalum nitride, so that capacitance can be increased.

It should be noted that many variations and modifications might be made to the embodiments described above without substantially departing from the principles of the present invention. All such variations and modifications are intended to be included herein within the scope of the present invention, as set forth in the following claims.

That which is claimed is:

1. A method of forming a capacitor, the method comprising:
forming a capacitor electrode layer including tantalum nitride using a tantalum precursor including tantalum elements and bonding elements that are chemically bonded to the tantalum elements.

2. A method according to claim 1 wherein the tantalum precursor comprises at least one of a tantalum amine derivative and/or a tantalum halide derivative.

3. A method according to claim 2 wherein the tantalum amine derivative comprises at least one of Ta(NR₁)(NR₂R₃)₃(where each of R₁, R₂, and R₃ are selected from an H and/or C₁-C₆ alkyl group), Ta(NR₁R₂)₅(where each of R₁ and R₂ are selected from an H and/or C₁-C₆ alkyl group), Ta(NR₁ R₂)ₓ (NR₃R₄)₅₋ₓ (where each of R₁, R₂, R₃ and R₄ are selected from H and/or C₁-C₆ alkyl group and x is selected from 1, 2, 3 or 4), or terbutylimido-tris-diethylamido tantalum (TBTDET:(Net₂)₃Ta=NBu^{t}).

4. A method according to claim 2 wherein the tantalum halide derivative comprises at least one of TaF₅, TaCl₅, TaBr₅ and/or Tal₅.

5. A method according to claim 1 wherein the tantalum precursor is ,introduced in a gaseous state.

6. A method according to claim 1 wherein forming the capacitor electrode layer includes forming the capacitor electrode layer at a temperature in a range of about 100° C. to about 650° C. and at a pressure in a range of about 0.3 to about 30 Torr.

7. A method according to claim 1, wherein at least a portion of the bonding elements include at least one ligand-bonded element that is ligand-bonded to a respective tantalum element.

8. A method according to claim 7 wherein forming the capacitor electrode comprises:
introducing the tantalum precursor to a substrate;
chemisorbing a portion of the tantalum precursor onto the substrate;
removing from the substrate a portion of the tantalum precursor that has not been chemisorbed onto the substrate; and
removing the ligand-bonded elements of the chemisorbed tantalum precursor from the chemisorbed tantalum precursor.

9. A method according to claim 8 wherein introducing the tantalum precursor, chemisorbing a portion of the tantalum precursor, removing a portion of the tantalum precursor, and removing the ligand-bonded elements are repeated at least once.

10. A method according to claim 8 further comprising:
removing a residual material around the substrate when removing the ligand-boded elements.

11. A method according to claim 8 wherein the non-chemisorbed tantalum precursor is removed using an inert gas.

12. A method according to claim 8 wherein the ligand-bonded elements are removed using a removing gas comprising at least one of H₂, N₂, NH₃, SiH₄, and/or Si₂H₆.

13. A method according to claim 12 wherein the removing gas is activated as a plasma remote from the substrate.

14. A method according to claim 8 further comprising:
after forming the capacitor electrode layer, treating the capacitor electrode layer using a post treatment gas comprising at least one of H₂, N₂, NH₃, SiH₄, and/or Si₂H₆.

15. A method according to claim 8 wherein the post treatment gas is activated as a plasma.

16. A method according to claim 1 wherein forming the capacitor electrode layer comprises:
introducing a tantalum amine derivative as the tantalum precursor to a substrate;
introducing at least one of H₂ gas, N₂ gas, and/or a compound gas including nitrogen (N) atom(s), to the substrate;
generating plasma ions of the at least one of the H₂ gas, the N₂ gas, and/or the compound gas including nitrogen (N) atom(s), and of the tantalum amine derivative; and
forming a thin film including tantalum nitride on the substrate by reacting the plasma ions with the substrate.

17. A method according to claim 16 further comprising:
after forming the thin film, post treating the thin film using a post treatment gas comprising at least one of H₂, NH₃, N₂, SiH₄, and/or Si₂H₆.

18. A method according to claim 17 wherein the post treatment gas is activated as a plasma.

19. A method according to claim 16 wherein the compound gas including nitrogen (N) atom(s) includes at least one of NH₃ gas or N₂H₂ gas.

20. A method according to claim 16 wherein the H₂ gas, the N₂ gas, and/or the compound gas including nitrogen (N) atom(s) is activated as a plasma.

21. A method according to claim 1 wherein forming the capacitor electrode is preceded by:
providing an integrated circuit substrate including a source/drain region therein, wherein the capacitor electrode is formed on the integrated circuit substrate and wherein the capacitor electrode is electrically coupled with the source/drain region.

22. A method according to claim 1 wherein forming the capacitor electrode is preceded by:
providing an integrated circuit substrate;
forming an initial capacitor electrode on the integrated circuit substrate; and
forming a capacitor dielectric layer on the initial capacitor electrode opposite the integrated circuit substrate, wherein the capacitor electrode layer is formed on the capacitor dielectric layer opposite the initial capacitor electrode.

23. A method according to claim 1 further comprising:
forming a dielectric layer on the capacitor electrode layer; and
forming an opposing capacitor electrode on the dielectric layer opposite the capacitor dielectric layer.

24. A method according to claim 23 wherein the dielectric layer comprises a metal oxide.

25. A method according to claim 24 wherein the metal oxide comprises at least one of Ta₂O₅, TiO₂, Al₂O₃, Y₂O₃, ZrO₂, HfO₂, BaTiO₃, and/or SrTiO₃.

26. A method according to claim 23 wherein the opposing capacitor electrode comprises a tantalum nitride layer.

27. A method according to claim 23 wherein the opposing capacitor electrode comprises at least one of polysilicon, ruthenium (Ru), platinum (Pt), iridium (Ir), titanium nitride (TaN), tantalum nitride (TaN), and/or tungsten nitride (WN).

28. A method according to claim 23 further comprising:
forming a capping layer on the opposing capacitor electrode opposite the dielectric layer.

29. A method according to claim 28 wherein the capping layer comprises tantalum nitride (TaN).

30. A method of forming an integrated circuit device, the method comprising:
forming a conductive layer including tantalum nitride on an integrated circuit substrate using a tantalum precursor including tantalum elements and bonding elements that are chemically bonded to the tantalum elements.

31. A method according to claim 30,wherein the tantalum precursor comprises at least one of a tantalum amine derivative and/or a tantalum halide derivative.

32. A method according to claim 31 wherein the tantalum amine derivative comprises at least one of Ta(NR₁)(NR₂R₃)₃(where each of R₁, R₂, and R₃ are selected from an H and/or C₁-C₆ alkyl group), Ta(NR₁R₂)₅ (where each of R₁ and R₂ are selected from an H and/or C₁-C₆ alkyl group), Ta(NR₁R₂)ₓ (NR₃R₄)₅₋ₓ(where each of R₁, R₂, R₃ and R₄ are selected from H and/or C₁-C₆ alkyl group and x is selected from 1, 2, 3 or 4), or terbutylimido-tris-diethylamido tantalum (TBTDET:(Net₂)₃Ta=NBu^{t}).

33. A method according to claim 31 wherein the tantalum halide derivative comprises at least one of TaF₅, TaCl₅, TaBr₅ and/or Tal₅.

34. A method according to claim 30 wherein the tantalum precursor is introduced in a gaseous state.

35. A method according to claim 30 wherein forming the conductive layer includes forming the conductive layer at a temperature in a range of about 100° C. to about 650° C. and at a pressure in a range of about 0.3 to about 30 Torr.

36. A method according to claim 30 wherein at least a portion of the bonding elements include at least one ligand-bonded element that is ligand-bonded to a respective tantalum element.

37. A method according to claim 36 wherein forming the conductive layer comprises:
introducing the tantalum precursor to the integrated circuit substrate;
chemisorbing a portion of the tantalum precursor onto the integrated circuit substrate;
removing from the integrated circuit substrate a portion of the tantalum precursor that has not been chemisorbed onto the integrated circuit substrate; and
removing the ligand-bonded elements of the chemisorbed tantalum precursor from the chemisorbed tantalum precursor.

38. A method according to claim 37 wherein introducing the tantalum precursor, chemisorbing a portion of the tantalum precursor, removing a portion of the tantalum precursor, and removing the ligand-bonded elements are repeated at least once.

39. A method according to claim 37 further comprising:
removing a residual material around the integrated circuit substrate when removing the ligand-boded elements.

40. A method according to claim 37 wherein the non-chemisorbed tantalum precursor is removed using an inert gas.

41. A method according to claim 37 wherein the ligand-bonded elements are removed using a removing gas comprising at least one of H₂, N₂, NH₃, SiH₄, and/or Si₂H₆.

42. A method according to claim 41 wherein the removing gas is activated as a plasma remote from the substrate.

43. A method according to claim 37 further comprising:
after forming the conductive layer, treating the conductive layer using a post treatment gas comprising at least one of H₂, N₂, NH₃, SiH₄, and/or Si₂H₆.

44. A method according to claim 37 wherein the post treatment gas is activated as a plasma.

45. A method according to claim 30 wherein forming the conductive layer comprises:
introducing a tantalum amine derivative as the tantalum precursor to the integrated circuit substrate;
introducing at least one of H₂ gas, N₂ gas, and/or a compound gas including nitrogen (N) atom(s), to the integrated circuit substrate;
generating plasma ions of the at least one of the H₂ gas, the N₂ gas, and/or the compound gas including nitrogen (N) atom(s), and of the tantalum amine derivative; and
forming a thin film including tantalum nitride on the integrated circuit substrate by reacting the plasma ions with the integrated circuit substrate.

46. A method according to claim 45 further comprising:
after forming the thin film, post treating the thin film using a post treatment gas comprising at least one of H₂, NH₃, N₂, SiH₄, and/or Si₂H₆.

47. A method according to claim 46 wherein the post treatment gas is activated as a plasma.

48. A method according to claim 45 wherein the compound gas including nitrogen (N) atom(s) includes at least one of NH₃ gas or N₂H₂ gas.

49. A method according to claim 45 wherein the H₂ gas, the N₂ gas, and/or the compound gas including nitrogen (N) atom(s) is activated as a plasma.

50. A method according to claim 30 wherein the integrated circuit substrate includes a source/drain region therein, and wherein the capacitor electrode is electrically coupled with the source/drain region.

51. A method according to claim 30 wherein forming the conductive layer is preceded by:
forming an initial capacitor electrode on the integrated circuit substrate; and
forming a capacitor dielectric layer on the initial capacitor electrode opposite the integrated circuit substrate, wherein the conductive layer is formed on the capacitor dielectric layer opposite the initial capacitor electrode.

52. A method according to claim 30 further comprising:
forming a dielectric layer on the conductive layer; and
forming an opposing capacitor electrode on the dielectric layer opposite the conductive layer.

53. A method according to claim 52 wherein the dielectric layer comprises a metal oxide.

54. A method according to claim 53 wherein the metal oxide comprises at least one of Ta₂O₅, TiO₂, Al₂O₃, Y₂O₃, ZrO₂, HfO₂, BaTiO₃, and/or SrTiO₃.

55. A method according to claim 52 wherein the opposing capacitor electrode comprises a tantalum nitride layer.

56. A method according to claim 52 wherein the opposing capacitor electrode comprises at least one of polysilicon, ruthenium (Ru), platinum (Pt), iridium (Ir), titanium nitride (TaN), tantalum nitride (TaN), and/or tungsten nitride (WN).

57. A method according to claim 52 further comprising:
forming a capping layer on the opposing capacitor electrode opposite the dielectric layer.

58. A method according to claim 57 wherein the capping layer comprises tantalum nitride (TaN).

59. A method of forming a capacitor on a semiconductor device, comprising:
forming a first electrode layer including tantalum nitride on a semiconductor substrate by using tantalum precursor including a tantalum element and bonding elements that are chemically bonded to the tantalum elements, wherein a part of the bonding elements include at least one ligand bonded element which is ligand-bonded to the tantalum element;
forming a dielectric layer on the first electrode layer; and
forming a second electrode layer on the dielectric layer.

60. A method of forming a capacitor on a semiconductor device, comprising:
forming a first electrode layer on a substrate;
forming a dielectric layer on the first electrode layer; and
forming a second electrode layer including tantalum nitride on the dielectric layer by using tantalum precursor including tantalum elements and bonding elements that are chemically bonded to the tantalum elements, wherein a part of the bonding elements include at least one ligand bonded element which is ligand-bonded to the tantalum element.
